(19) United States
(12) Patent Application Publication
(10) Pub. No.: US 2022/0397784 A1
(43) Pub. Date: Dec. 15, 2022

(54) DISPLAY PANEL, METHOD FOR MANUFACTURING DISPLAY PANEL, AND DISPLAY DEVICE

(71) Applicants: Beijing BOE Display Technology Co., Ltd., Beijing (CN); BOE Technology Group Co., Ltd., Beijing (CN)

(72) Inventors: Song YANG, Beijing (CN); Pengxia LIANG, Beijing (CN); Shiyu ZHANG, Beijing (CN); Jiahui HAN, Beijing (CN); Ge SHI, Beijing (CN); Yanliu SUN, Beijing (CN); Zheng FANG, Beijing (CN); Hongpeng LI, Beijing (CN); Hyunsic CHOI, Beijing (CN); Zhenyu ZHANG, Beijing (CN)

(21) Appl. No.: 17/612,090

(22) PCT Filed: Dec. 25, 2020
(86) PCT No.: PCT/CN2020/139517

§ 371 Date: Nov. 17, 2021

(51) Int. Cl. G02F 1/1368; G02F 1/141; H01L 27/12

(52) U.S. Cl. CPC G02F 1/1368; G02F 1/141; H01L 27/1251; H01L 27/127

(57) ABSTRACT

The present disclosure discloses a display panel, a method for manufacturing a display panel, and a display device, and belongs to the field of liquid crystal display technologies. The display panel includes an array substrate, a counter substrate, and a liquid crystal layer between the array substrate and the counter substrate. For the array substrate, a diffuse reflection layer is sequentially laminated on the array substrate. The array substrate includes a first base substrate, and a thin film transistor array, a diffuse reflection layer, and a first planarization layer that are laminated on the first base substrate. A surface of the diffuse reflection layer proximal to the first planarization layer is a reflection surface that has a plurality of protrusion structures, the protrusion structures are configured to diffusely reflect light irradiated on the reflection surface. Based on this structure, the first planarization layer may separate the protrusion structure from the liquid crystal layer to prevent the protrusion structure from affecting the driving effect of the liquid crystal layer. In this way, the problem in the related art regarding the poor display effect of the display panel is solved and thus the display effect of the display panel is improved.

### CROSS-REFERENCE TO RELATED APPLICATIONS

This application is a U.S. national stage of international application No. PCT/CN2020/139517, filed on Dec. 25, 2020, the disclosure of which is herein incorporated by reference in its entirety.

### TECHNICAL FIELD

The present disclosure relates to the field of liquid crystal display technologies, and in particular to a display panel, a method for manufacturing a display panel, and a display device.

### BACKGROUND

In recent years, liquid crystal display panels is widely applied in televisions, mobile phones, and other fields due to their advantages of low power consumption, good display effect, and high response speed.

### SUMMARY

Embodiments of the present disclosure provide a display panel. The technical solutions are as follows.

In an aspect of the embodiments of the present disclosure, a display panel is provided. The display panel includes: an array substrate, a counter substrate, and a liquid crystal layer between the array substrate and the counter substrate; wherein the array substrate includes a first base substrate, and a thin film transistor array, a diffuse reflection layer, and a first planarization layer that are laminated on the first base substrate, wherein a surface, proximal to the first planarization layer, of the diffuse reflection layer is a reflection surface, the reflection surface being provided with a plurality of protrusion structures, the protrusion structures being configured to diffusely reflect light irradiated on the reflection surface.

Optionally, the array substrate further includes a plurality of support blocks between the diffuse reflection layer and the first base substrate, wherein the plurality of support blocks are disposed in orthographic projections of the plurality of protrusion structures on the first base substrate in one-to-one correspondence with the plurality of protrusion structures.

Optionally, the thin film transistor array includes a plurality of thin film transistors arranged in an array on the first base substrate, wherein the thin film transistor includes a first electrode, a second electrode, and a third electrode configured to control connection or disconnection between the first electrode and the second electrode; and the support block and the first electrode in the thin film transistor are disposed in a same layer.

Optionally, the array substrate further includes a support plate on which the plurality of support blocks are disposed.

Optionally, the support plate and the third electrode in the thin film transistor are disposed in a same layer.

Optionally, the protrusion structure is a cambered protrusion structure, and a ratio of a diameter of the protrusion structure to a height of the protrusion structure in a direction perpendicular to the first base substrate satisfies 3:1 to 15:1.

Optionally, the protrusion structure is formed by melting and cooling a columnar protrusion.

Optionally, an orthographic projection of the protrusion structure on the first base substrate is square, and the orthographic projections of the plurality of protrusion structures on the first base substrate are arranged in rows and columns; or an orthographic projection of the protrusion structure on the first base substrate is circular, and the orthographic projections of the plurality of protrusion structures on the first base substrate are arranged in a form of honeycomb; or an orthographic projection of the protrusion structure on the first base substrate is hexagonal, and the orthographic projections of the plurality of protrusion structures on the first base substrate are arranged in a form of honeycomb.

Optionally, the display panel further includes a first electrode layer on a side, proximal to the first planarization layer, of the liquid crystal layer, and a second electrode layer on a side, distal from the first planarization layer, of the liquid crystal layer; and the display panel further includes a plurality of spacers including a first spacer, wherein an end of the first spacer abuts against the second electrode layer, and another end passes through the liquid crystal layer and abuts against the first electrode layer.

Optionally, the thin film transistor array includes a plurality of thin film transistors arranged in an array on the first base substrate, wherein the thin film transistor includes a first electrode, a second electrode, and a third electrode configured to control connection or disconnection between the first electrode and the second electrode; and the first planarization layer is provided with a first through hole through which the first electrode layer is electrically connected to the first electrode, and an orthographic projection of the another end of the first spacer on the first planarization layer is disposed at the first through hole.

Optionally, the diffuse reflection layer includes a protrusion structure layer and a metal reflection layer covering the protrusion structure layer, wherein the protrusion structure layer is provided with a second through hole through which the metal reflection layer is electrically connected to the first electrode, and through which the first electrode layer is electrically connected to the metal reflection layer.

Optionally, the counter substrate includes a second base substrate, and a third planarization layer and the second electrode layer laminated on a side, proximal to the liquid crystal layer, of the second base substrate; and the counter substrate further includes an adhesive structure, and the second electrode layer is provided with at least one opening in which the adhesive structure is disposed.

Optionally, the liquid crystal layer includes ferroelectric liquid crystal.

Optionally, the thin film transistor array includes a plurality of thin film transistors arranged in an array on the first base substrate; and the array substrate further includes a second planarization layer between the plurality of thin film transistors and the diffuse reflection layer.

Optionally, the protrusion structure is a spherical protrusion structure, and a ratio of a diameter to a radius of the protrusion structure satisfies 1.3:1 to 1.6:1; the display panel further includes a plurality of support blocks between the diffuse reflection layer and the first base substrate, wherein the plurality of support blocks are disposed in orthographic projections of the plurality of protrusion structures on the first base substrate in one-to-one correspondence with the plurality of protrusion structures; the thin film transistor array includes a plurality of thin film transistors arranged in an array on the first base substrate, wherein the thin film transistor includes a first electrode, a second electrode, and a third electrode configured to control connection or disconnection between the first electrode and the second electrode, and the support block and the first electrode in the thin film transistor are disposed in a same layer; an orthographic projection of the protrusion structure on the first base substrate is square, and the orthographic projections of the plurality of protrusion structures on the first base substrate are arranged in rows and columns; the display panel further includes a first electrode layer on a side, proximal to the first planarization layer, of the liquid crystal layer, and a second electrode layer on a side, distal from the first planarization layer, of the liquid crystal layer; the display panel further includes a plurality of spacers comprising a first spacer, wherein an end of the first spacer abuts against the second electrode layer, and another end passes through the liquid crystal layer and abuts against the first electrode layer; and the first planarization layer is provided with a first through hole through which the first electrode layer is electrically connected to the first electrode, and an orthographic projection of the another end of the first spacer on the first planarization layer is disposed at the first through hole.

In another aspect of the embodiments of the present disclosure, a method for manufacturing a display panel is provided. The method includes: acquiring an array substrate; and forming a display panel including the array substrate, a liquid crystal layer, and a counter substrate; wherein the array substrate includes a first base substrate, and a thin film transistor array, a diffuse reflection layer, and a first planarization layer that are laminated on the first base substrate, wherein a surface, proximal to the first planarization layer, of the diffuse reflection layer is a reflection surface, the reflection surface being provided with a plurality of protrusion structures, the protrusion structures being configured to diffusely reflect light irradiated on the reflection surface.

Optionally, acquiring the array substrate includes: acquiring a first base substrate; forming the thin film transistor array on the first base substrate; forming a structure layer having a plurality of columnar protrusions on the first base substrate on which the thin film transistor array is formed; transforming the structure layer into the diffuse reflection layer by heating and melting the plurality of columnar protrusions into cambered protrusions; and forming the first planarization layer on the first base substrate on which the diffuse reflection layer is formed.

Optionally, acquiring the array substrate includes: acquiring a first base substrate; forming the thin film transistor array and a plurality of support blocks on the first base substrate, wherein the thin film transistor array includes a plurality of thin film transistors arranged in an array on the first base substrate, the thin film transistor including a first electrode, a second electrode, and a third electrode configured to control connection or disconnection between the first electrode and the second electrode, and the support block and the first electrode in the thin film transistor are formed by a same patterning process; and forming the diffuse reflection layer and the first planarization layer on the first base substrate on which the thin film transistor array is formed, wherein the plurality of protrusion structures are formed on a surface, proximal to the first planarization layer, of the diffuse reflection layer under supports of the plurality of support blocks.

In still another aspect of the embodiments of the present disclosure, a display device is provided. The display device includes a display panel as defined in any one of the above aspects.

The technical solutions according to embodiments of the present disclosure at least achieve the following beneficial effects.

A display panel is provided, wherein the display panel includes an array substrate, a diffuse reflection layer, a planarization layer, and a liquid crystal layer that are laminated. The first planarization layer between the diffuse reflection layer and the liquid crystal layer is capable of overcoming impacts caused by the protrusion structure disposed on the diffuse reflection layer on the driving effect of the liquid crystal layer. In addition, the protrusion structure is capable of diffusely reflecting the light irradiated to the surface thereof, such that a reflective display panel with a good display effect is achieved. Therefore, the problem in the related art regarding the poor display effect of the display panel is solved, and the display effect of the display panel is improved.

### BRIEF DESCRIPTION OF THE DRAWINGS

For clearer descriptions of the technical solutions in the embodiments of the present disclosure, the following briefly introduces the accompanying drawings required for describing the embodiments. Apparently, the accompanying drawings in the following description show merely some embodiments of the present disclosure, and persons of ordinary skill in the art may still derive other drawings from these accompanying drawings without creative efforts.

FIG. 1 is a schematic structural diagram of a display panel according to an embodiment of the present disclosure;

FIG. 2 is an optical path diagram of a protrusion structure according to an embodiment of the present disclosure;

FIG. 3 is a schematic structural diagram of a protrusion structure according to an embodiment of the present disclosure;

FIG. 4 is a schematic structural diagram of a thin film transistor of a display panel according to an embodiment of the present disclosure;

FIG. 5 is a schematic structural diagram in the case that the protrusion structures shown in FIG. 1 are arranged in a square aligning fashion;

FIG. 6 is a schematic structural diagram when the protrusion structures shown in FIG. 1 are arranged in a circular staggering fashion;

FIG. 7 is a schematic structural diagram when the protrusion structures shown in FIG. 1 are arranged in a regular hexagonal staggering fashion;

FIG. 8 is a supporting fashion according to an embodiment of the present disclosure;

FIG. 9 is another supporting fashion according to an embodiment of the present disclosure;

FIG. 10 is a top view of a second electrode layer of the display panel shown in FIG. 1;

FIG. 11 is a schematic structural diagram of another display panel according to an embodiment of the present disclosure;

FIG. 12 is a method for manufacturing a display panel according to an embodiment of the present disclosure;

FIG. 13 is a flowchart of forming an array substrate in the embodiment shown in FIG. 12; and

FIG. 14 is another flowchart of forming an array substrate in the embodiment shown in FIG. 12.

Through the aforementioned drawings, specific embodiments of the present disclosure have been shown and will be described in detail hereinafter. The drawings and written descriptions are not intended to limit the scope of the concepts of the present disclosure in any way, but rather to illustrate the concepts of the present disclosure to a person of ordinary skill in the art by referring to specific embodiments.

### DETAILED DESCRIPTION

In order to make the object, technical solutions, and advantages of the present disclosure clearer, the embodiments of the present disclosure are described in detail hereinafter with reference to the accompanying drawings.

In the related art, a display panel generally includes an array substrate, a reflective structure layer, a planarization layer, and a liquid crystal layer that are laminated. A thin film transistor in the array substrate is configured to drive liquid crystal in the liquid crystal layer to twist, thereby controlling to emit the light or not, such that the object of display is achieved. The reflective structure layer includes a plurality of protrusions, and therefore the light irradiated on the reflective structure layer may be diffusely reflected by the surface of the protrusion, such that a reflectivity of the reflective display panel is increased, and the performance of the reflective display panel is further improved.

However, the plurality of protrusions in the reflective structure layer may affect the driving effect of the thin film transistor to the liquid crystal, thereby causing a poor display effect of the display panel.

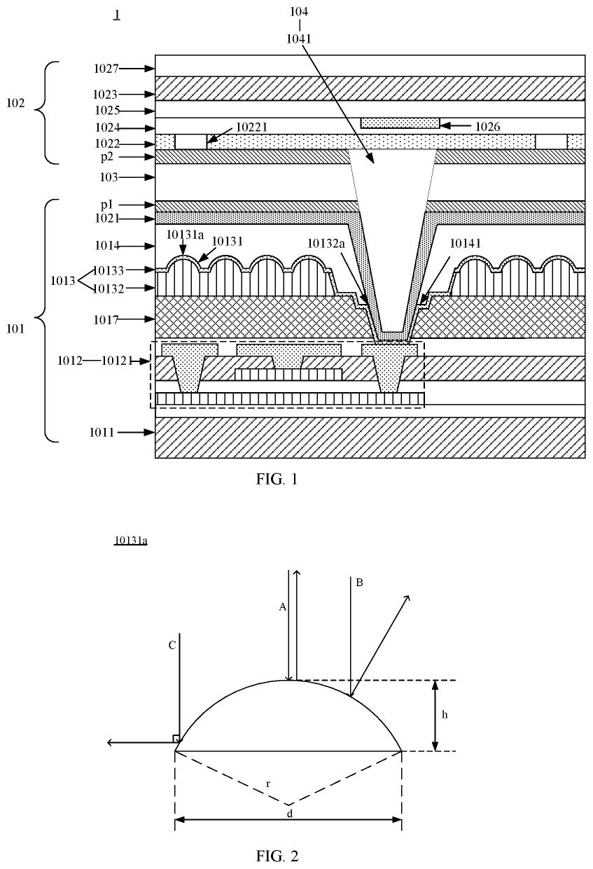

FIG. 1 is a schematic structural diagram of a display panel according to an embodiment of the present disclosure. The display panel 1 includes: an array substrate 101, a counter substrate 102, and a liquid crystal layer 103 between the array substrate 101 and the counter substrate 102.

The array substrate 101 includes a first base substrate 1011, and a thin film transistor array 1012, a diffuse reflection layer 1013, and a first planarization layer 1014 that are laminated on the first base substrate 1011. A surface, proximal to the first planarization layer 1014, of the diffuse reflection layer 1013 is a reflection surface 10131, wherein the reflection surface is provided with a plurality of protrusion structures 10131a, the protrusion structures 10131a being configured to diffusely reflect light irradiated on the reflection surface.

As shown in FIG. 1, the light irradiated to the protrusion structures 10131a may be diffusely reflected by the surface of the protrusion structures 10131a. The diffuse reflection refers to a phenomenon that energy is reflected isotropically in all directions. In this way, the reflectivity of the display panel to incident light from various angles may be constant (the reflectivity refers to a percentage of radiant energy reflected by an object to the total radiant energy; the higher the reflectivity, the less energy loss; and conversely, the lower the reflectivity, the more energy loss), which further improves the display effect of the display panel 1, In addition, the first planarization layer 1014 is disposed between the diffuse reflection layer 1013 and the liquid crystal layer 103, and configured to flatten the protrusion structure 10131a on the diffuse reflection layer 1013. According to this structure, the protrusion structure 10131a on the diffuse reflection layer 1013 is spaced from the liquid crystal layer 103 by the first planarization layer 1014, and is this hardly in direct contact with the liquid crystal layer 103, such that the protrusion structure 10131a is prevented from causing impacts to the driving effect of the liquid crystal in the liquid crystal layer 103. Therefore, the normal driving of the liquid crystal in the liquid crystal layer is ensured while the reflectivity of the display panel is improved.

In summary, the embodiment of the present disclosure provides a display panel. The display panel includes an array substrate, a counter layer, and a liquid crystal layer that are laminated. The first planarization layer between the diffuse reflection layer of the array substrate and the liquid crystal layer is capable of overcoming impacts caused by the protrusion structure disposed on the diffuse reflection layer on the driving effect of the liquid crystal layer. In addition, the protrusion structure is capable of diffusely reflecting the light irradiated to the surface thereof, such that a reflective display panel with a good display effect is achieved. Thus, the problem in the related art regarding the poor display effect of the display panel is solved, and the display effect of the display panel is improved.

Optionally, FIG. 2 is an optical path diagram of a protrusion structure according to an embodiment of the present disclosure. As shown in FIG. 2, optionally, the protrusion structure 10131a is a cambered protrusion structure, and a ratio of a diameter r of the protrusion structure 10131a to a height h of the protrusion structure 10131a in a direction perpendicular to the first base substrate satisfies 3:1 to 15:1. An orthographic projection of the protrusion structure 10131a on the first base substrate may be square, circular, hexagonal, or in other shapes.

In the case that the orthographic projection of the protrusion structure 10131a on the first base substrate is circular, the diameter of the protrusion structure may refer to a diameter of the circular orthographic projection. In the case that the orthographic projection of the protrusion structure 10131a on the first base substrate is square, the diameter of the protrusion structure may refer to a diameter of an inscribed circle of the square orthographic projection. In the case that the orthographic projection of the protrusion structure 10131a on the first base substrate is hexagonal, the diameter of the protrusion structure may refer to a diameter of an inscribed circle of the hexagonal orthographic projection. Similarly, in the case that the orthographic projection of the protrusion structure 10131a on the first base substrate is in other shapes, the diameter of the protrusion structure may refer to a diameter of an inscribed circle of the orthographic projection in the corresponding shape.

In addition, it should be noted that in the case that the orthographic projection of the protrusion structure 10131a on the first base substrate is circular, a top surface of the protrusion structure 10131a is a cambered surface; and in the case that the orthographic projection of the protrusion structure 10131a on the first base substrate is in other non-circular shapes, the surface of the protrusion structure 10131a include a cambered surface and a surface extending from edges of the cambered surface.

In addition, the protrusion structure may also be a spherical protrusion structure, and a ratio of a diameter d to the radius r of the protrusion structure 10131a satisfies 1.3:1 to 1.6:1. For example, the ratio may be 1.414:1. The spherical radius r of the protrusion structure 10131a may range from 2.12 nanometers to 10.6 nanometers.

In response to the light outside the display panel being incident on the protrusion structure 10131a, the incident light may correspond to different incident angles on the surface of the protrusion structure 10131a. In an exemplary embodiment, as shown in FIG. 2, the incident angles of three light rays A, B, and C on the surface of the protrusion structure 10131a are sequentially increased, and the protrusion structure 10131a may reflect, in the range of 0 to 90 degrees, the light rays with different incident angles. That is, an effect similar to Lambertian reflection is achieved. The Lambertian reflection effect herein is also named as scattering reflection, which refers to receiving, from all directions on the surface, incident light and diverging all incident light.

In addition, the light ray C is incident on the edge of the protrusion structure 10131a, where an angle between the incident light and the reflected light is 90 degrees. Thus, a tangent angle of the edge of the protrusion structure 10131a is 45 degrees. In this way, a better reflection effect and a better optical performance of the protrusion structure 10131a are achieved.

Optionally, the diameter d of the protrusion structure 10131a may range from 3 nanometers to 15 nanometers. Based on this structure, it is possible to provide as many protrusion structures 10131a as possible on the diffuse reflection layer 1013 to increase the reflectivity of the diffuse reflection layer 1013 and thereby improve the optical performance of the diffuse reflection layer,

Optionally, an arch height h of the protrusion structure 10131a may range from 0.6 nanometers to 3.1 nanometers, wherein the arch height h is a height of the protrusion structure 10131a in a direction perpendicular to the first base substrate.

Furthermore, referring to FIG. 1, the protrusion structure 10131a has a cambered surface. In the case that the liquid crystal layer and the electrodes on both sides of the liquid crystal layer are directly disposed on the diffuse reflection layer 1013 having a plurality of the protrusion structures 10131a, electric field lines generated by the electrodes on both sides of the liquid crystal layer may be not completely perpendicular to the surface of the display panel, which may interfere with the driving of the liquid crystal in the liquid crystal layer. In addition, on a surface of the diffuse reflection layer 1013 facing the liquid crystal layer, an area provided with the protrusion structures 10131a has a height difference with other areas with no protrusion structures 10131a. Thus, in the case that the liquid crystal layer is directly disposed on the protrusion structures 10131a, a thickness of the liquid crystal layer may fluctuate within a range due to the protrusion structure 10131a, which may affect the reflectivity of the display panel 1 and reduce the display effect of the display panel. Thus, the first planarization layer 1014 is disposed between the diffuse reflection layer 1013 and the liquid crystal layer 103 to flatten the diffuse reflection layer 1013, such that the driving effect of the liquid crystal is not affected by the protrusion structure 10131a, and a good display effect of the display panel is achieved.

Optionally, the protrusion structure is formed by melting and cooling a columnar protrusion. A plurality of columnar protrusions are heated and melted to form cambered surfaces, and then shaped and fixed by cooling to thereby form the protrusion structure.

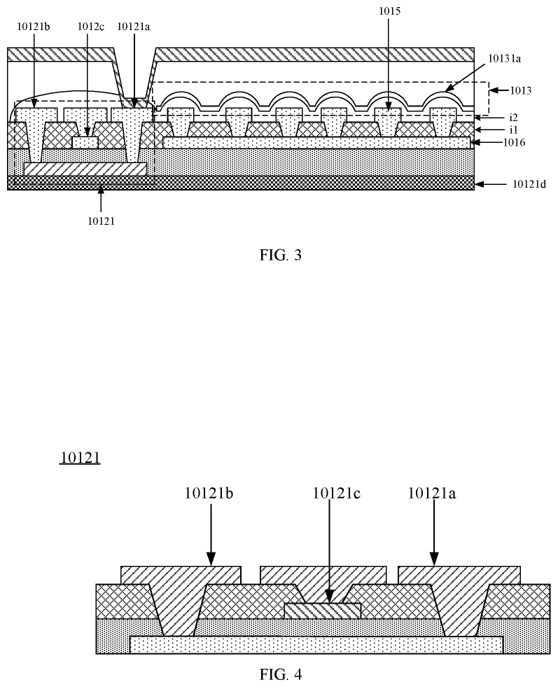

Optionally, FIG. 3 is a schematic structural diagram of a protrusion structure according to an embodiment of the present disclosure. In order to make the diagram clear, FIG. 3 also shows the structure of the array substrate. As shown in FIG. 3, the array substrate 101 includes a plurality of support blocks 1015 between the diffuse reflection layer 1013 and the first base substrate 1011, wherein the plurality of support blocks 1015 are disposed in the orthographic projections of the plurality of protrusion structures 10131a on the first base substrate 1011 in one-to-one correspondence with the plurality of protrusion structures. The support block 1015 is disposed between the diffuse reflection layer 1013 and the array substrate 101, and supports a corresponding position of the diffuse reflection layer 1013 to form the protrusion structure 10131a. A projection area of the protrusion structure 10131a on the array substrate 101 is greater than the projection area of the support block 1015 on the array substrate 101.

Optionally, the thin film transistor array 1012 includes a plurality of thin film transistors 10121 arranged in an array on the first base substrate 1011. The thin film transistor 10121 includes a first electrode 10121a, a second electrode 10121b, and a third electrode 10121c configured to control connection or disconnection between the first electrode 10121a and the second electrode 10121b, wherein the support block 1015 and the first electrode 10121a in the thin film transistor 10121 are disposed in a same layer. FIG. 4 is a schematic structural diagram of a thin film transistor of a display panel according to an embodiment of the present disclosure. The thin film transistor 10121 further includes an active layer 10121d, and a voltage applied on the third electrode 10121c may form a path in the active layer 10121d to conduct the first electrode 10121a and the second electrode 10121b.

The thin film transistor (TFT) belongs to an insulated gate field effect transistor. Liquid crystal pixels in the display panel may be driven to twist via the thin film transistor to control whether to emit the light or not, thereby achieving a display effect of a high speed and a high brightness. In practical applications, the thin film transistor serves as a switch. The thin film transistor includes a source electrode, a drain electrode, and a gate electrode. In applications of the thin film transistor, the gate electrode is configured to control connection and disconnection between the source electrode and the drain electrode. In response to a forward voltage applied to the gate electrode being greater than an applied voltage, the source electrode and drain electrode are connected; and in response to the forward voltage applied to the gate electrode being equal to zero or being a negative voltage, the source electrode and drain electrode are disconnected.

Therefore, the first electrode 10121a is one of the source and drain electrodes, the second electrode 10121b is the other of the source and drain electrodes, and the third electrode 10121c is the gate electrode of the thin film transistor 10121.

Referring to FIG. 3, the support block 1015 and the first electrode 10121a of the thin film transistor 10121 are formed in a same layer. The support block 1015 may be disposed in the same layer and formed by a same material as the first electrode 10121a of the thin film transistor 10121. That is, the support block 1015 and the first electrode 10121a may be formed by a one patterning process.

In embodiments of the present disclosure, the involved patterning process may include processes of coating photoresist, exposing, developing, etching, and stripping the photoresist.

Optionally, the array substrate 101 further includes a support plate 1016 on which the plurality of support blocks 1015 are disposed. The support block 1015 is configured to support the protrusion structure 10131a, and the support plate 1016 is configured to support each support block 1015 to improve structural stability of the protrusion structure 10131a.

Optionally, the support plate 1016 and the gate electrode in the thin film transistor 10121 are disposed in a same layer. The gate electrode of the thin film transistor 10121 is the third electrode 10121c. The support plate 1016 may be provided in the same layer and made of the same material as the third electrode 10121c. That is, the support plate 1016 and the third electrode 10121c may be formed by a one patterning process. The support plate 1016 in the display panel may not be electrically connected to circuit traces in the display panel.

Based on this structure, a manufacturing process of the display panel 1 may be simplified, and the manufacturing difficulty and manufacturing cost of the display panel 1 may be reduced.

Optionally, the display panel 1 further includes a first insulating layer i1 and a second insulating layer i2. The first insulating layer i1 may be a gate insulating layer, and the second insulating layer i2 may be a source-drain insulating layer.

FIG. 3 shows a case where the support block 1015 is in contact with the support plate 1016 via an opening on the first insulating layer i1. In addition, the first insulating layer i1 may not be provided with an opening at the position corresponding to support block 1015, such that the support block 1015 is not in contact with the support plate 1016 and is disposed on the first insulating layer i1.

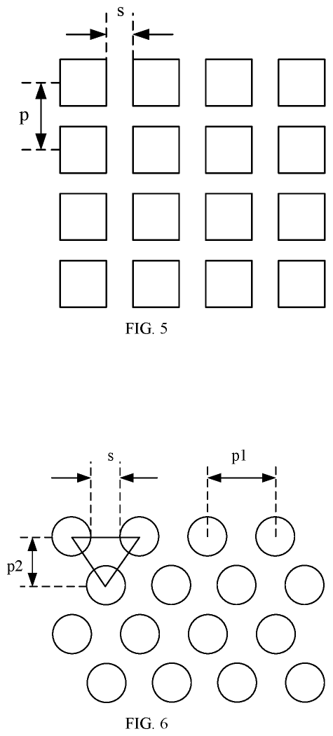

Optionally, FIG. 5 is a schematic structural diagram in the case that the protrusion structures shown in FIG. 1 are arranged in a square aligning fashion. Referring to FIG. 5, the orthographic projection of the protrusion structure on the first base substrate is square, and the orthographic projections of the plurality of protrusion structures on the first base substrate are arranged in rows and columns. The arrangement unit of the protrusion structures herein is square. The distance between each arrangement units is named as a space s, and the distance between a center of each arrangement unit and a center of the adjacent arrangement unit is named as a pitch p. In embodiments of the present disclosure, the space may range from 0.5 nanometers to 3 nanometers. Corresponding to the value range of the space, the pitch may range from 3.5 nanometers to 18 nanometers. The pitch may be divided into a horizontal pitch (p1) and a vertical pitch (p2). The horizontal pitch refers to the distance between the center of the arrangement unit and the center of the adjacent arrangement unit in the horizontal direction, and the vertical pitch refers to the distance between the center of the arrangement unit and the center of the arrangement unit adjacent in the vertical direction. in an exemplary embodiment, as shown in FIG. 5, in the case that the orthographic projection of the protrusion structure on the first base substrate is square, which indicates that the arrangement unit of the protrusion structures is square-shaped, the value of the horizontal pitch is equal to the value of the vertical pitch. In addition, the diameter of the protrusion structure under this arrangement fashion is the diameter of the inscribed circle of the square in FIG. 5.

Optionally, FIG. 6 is a schematic structural diagram in the case that the protrusion structures shown in FIG. 1 are arranged in a circular staggering fashion. Referring to FIG. 6, the orthographic projection of the protrusion structure on the first base substrate is circular, and the orthographic projections of the plurality of protrusion structures on the first base substrate are arranged in a form of honeycomb. The diameter of the protrusion structure under this arrangement fashion is the diameter of the circle in FIG. 6.

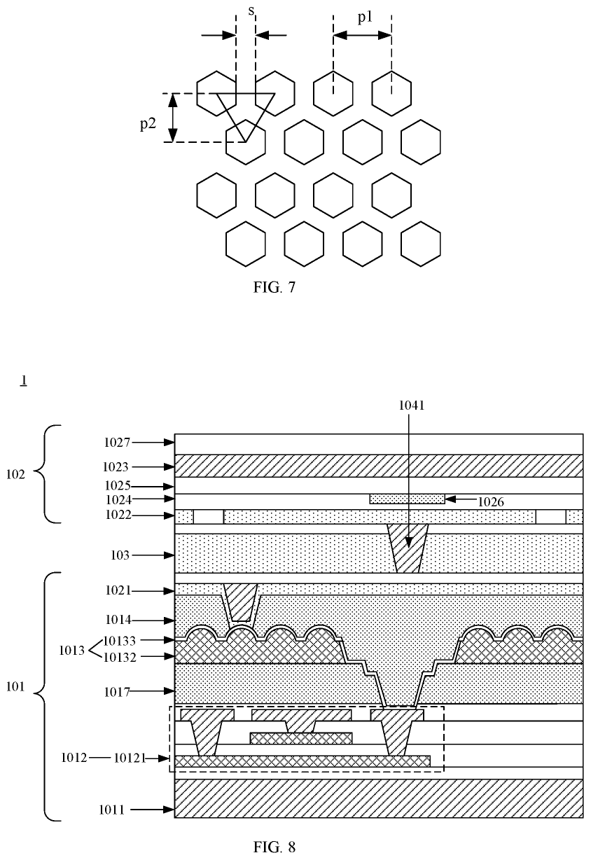

Optionally, FIG. 7 is a schematic structural diagram in the case that the protrusion structures shown in FIG. 1 are arranged in a regular hexagonal staggering fashion. Referring to FIG. 7, the orthographic projection of the protrusion structure on the first base substrate is regular hexagonal, and the orthographic projections of the plurality of protrusion structures on the first base substrate are arranged in a form of honeycomb. In the case that the protrusion structures are arranged in the regular hexagonal staggering fashion, the horizontal pitch equals to (2/1.732) multiplied by the vertical pitch. In addition, the diameter of the protrusion structure under this arrangement fashion is the diameter of the inscribed circle of the regular hexagon in FIG. 7.

The arrangement of the protrusion structures may also be implemented in other possible fashions, which is not limited in the embodiments of the present disclosure.

Optionally, referring to FIG. 1, the display panel includes a first electrode layer 1021 on a side, proximal to the first planarization layer 1014, of the liquid crystal layer 103, and a second electrode layer 1022 on a side, distal from the first planarization layer 1014, of the liquid crystal layer 103. The first electrode layer 1021 and the second electrode layer 1022 is a transparent conductive glass, which is commonly known as conductive film. The conductive film may be a thin film acquired by sputtering a transparent indium tin oxide (ITO) conductive thin film plating on a transparent organic thin film material in a magnetron sputtering fashion followed by a high temperature annealing treatment. The first electrode layer 1021 may be a pixel electrode layer. In applications of the display panel, the first electrode layer 1021 is electrically connected to the first electrode 10121a of the thin film transistor 10121, and meanwhile cooperates with the second electrode layer 1022 to construct a longitudinal (a direction perpendicular to the surface of the display panel) electric field. Based on this stricture, the thin film transistor 10121 may be able to drive the liquid crystal in the liquid crystal layer 103, thereby achieving the display function of the display panel 1.

The display panel 1 includes a plurality of spacers 104 comprising a first spacer 1041. An end of the first spacer 1041 abuts against the second electrode layer 1022, and the other end passes through the liquid crystal layer 103 and abuts against the first electrode layer 1021. Referring to FIG. 1, a cross section of the first spacer 1041 is trapezoid-shaped. A larger end of the trapezoid is connected to the second electrode layer 1022, and a smaller end is connected to the first electrode layer 1021, which means that the first spacer 1041 penetrates through the liquid crystal layer 103.

Optionally, as shown in FIG. 1 and FIG. 4, the thin film transistor array 1012 includes a plurality of thin film transistors 10121 arranged in an array on the first base substrate 1011. The thin film transistor 10121 includes a first electrode 10121a, a second electrode 10121b, and a third electrode 10121c configured to control connection or disconnection between the first electrode 1012a and the second electrode 10121b. The first planarization layer 1014 is provided with a first through hole 10141 through which the first electrode layer 1021 is electrically connected to the first electrode 10121a, and the orthographic projection of the other end of the first spacer 1041 on the first planarization layer 1014 is positioned at the first through hole 10141. That is, the first spacer extends into the through hole on the first planarization layer after extending out of the liquid crystal layer. Based on this structure, the first spacer is enabled to have a longer length, which facilitates the manufacturing. Correspondingly, the thickness of the liquid crystal layer may be thin without referring to the length of the spacer.

Optionally, the diffuse reflection layer 1013 includes a protrusion structure layer 10132 and a metal reflection layer 10133 covering the protrusion structure layer 10132. The protrusion structure layer 10132 is provided with a second through hole 10132a, at which the metal reflection layer 10133 is electrically connected to the first electrode 10121a and at which the first electrode layer 1021 is electrically connected to the metal reflection layer 10133. The protrusion structure layer 10132 in the diffuse reflection layer 1013 is configured to form the shape of the Lambertian reflection surface, and the metal reflection layer 10133 covering the protrusion structure layer 10132 is configured to achieve a high reflection function of the Lambertian reflection surface. The metal reflection layer 10133 may include silver or aluminum.

The first electrode layer 1021, the metal reflection layer 10133, and the first electrode 10121a are electrically connected to each other at a side proximal to the first electrode 10121a via the first through hole 10141 on the first planarization layer 1014 and the second through hole 10132a on the protrusion structure layer 10132. Based on this structure, a current may flow through the metal reflection layer 10133, and the liquid crystal in the liquid crystal layer 103 may be driven by cooperation of the metal reflection layer, the first electrode layer 1021, and the first electrode 10121a, thereby achieving the display effect.

The first through hole 10141 and the second through hole 10132a overlap with each other to form a deep hole in which the spacer 104 is disposed. Furthermore, a height of the spacer 104 (a dimension in a direction perpendicular to the surface of the display panel) is a sum of the thickness of the liquid crystal layer 103 and a height of the deep hole. The spacer 104 is configured to support the liquid crystal layer 103, and meanwhile control the thickness of the space between the substrates in the display panel 1 and keep the thickness uniformity of the space between the substrates. The spacer 104 may include an organic material with a mechanical strength.

Meanwhile, in the case that the spacer 104 is embedded in the deep hole, the thickness of the display panel 1 may be effectively reduced, and the range of the thickness may be controlled between 1.38 nanometers and 1.6 nanometers. In addition, the application range of the display panel may be extended.

FIG. 8 shows a supporting fashion according to an embodiment of the present disclosure. As shown in FIG. 8, the spacer 104 includes a plurality of first spacers 1041. One of the first spacers 1041 is trapezoid-shaped and penetrates through the liquid crystal layer, and the other first spacer 1041 is disposed between the diffuse reflection layer 1013 and the liquid crystal layer 103.

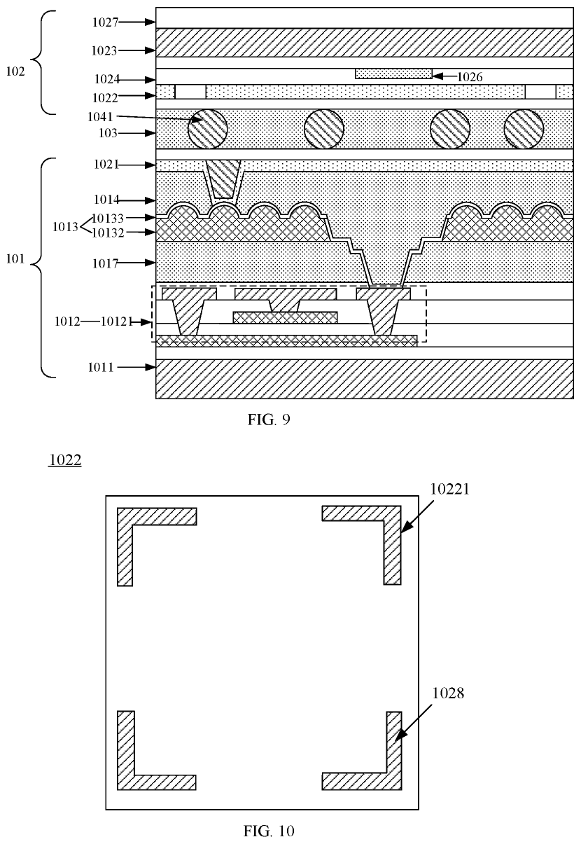

FIG. 9 shows another supporting fashion according to an embodiment of the present disclosure. As shown in FIG. 9, the spacer 104 includes a plurality of first spacers 1041 that are sphere. A diameter of the sphere matches with the thickness of the liquid crystal layer, and the first spacers 1041 are arranged in the liquid crystal layer 103 with a distance, to thereby uniformly support the liquid crystal layer 103.

Optionally, referring to FIG. 1, the array substrate further includes a first alignment layer p1 on a side, proximal to the first base substrate, of the liquid crystal layer 103. The counter substrate 102 further includes a second alignment layer p2 on a side, distal from the first base substrate, of the liquid crystal layer 103.

Furthermore, in response to the liquid crystal in the liquid crystal layer being not powered, the liquid crystal has no phase control ability, and is orientated dispersedly; and in response to the liquid crystal being powered, the liquid crystal is orientated and arranged uniformly.

Optionally, the counter substrate 102 includes a second base substrate 1023, and a third planarization layer 1024 and the second electrode layer 1022 laminated on a side, proximal to the liquid crystal layer 103, of the second base substrate 1021. The second base substrate 1023 serves to support the display panel 1, and may be made of glass or plastic material; and the third planarization layer 1024 is disposed on a surface, distal from the liquid crystal layer 103, of the second electrode layer 1022. FIG. 10 is a top view of a second electrode layer of the display panel shown in FIG. 1. As shown in FIG. 10, the counter substrate further includes an adhesive structure 1028, and the second electrode layer 1022 is provided with at least one opening 10221 in which the adhesive structure 1028 is disposed. The width of the opening 10221 may range from 0.1 millimeter to 1 millimeter. Based on this structure, the adhesion between the third planarization layer 1024 and the second electrode layer 1022 are strengthened, which avoids the falling off possibility of the second electrode layer 1022, and improves the stability of the entire display panel.

Meanwhile, the counter substrate further includes a plurality of sub-pixel areas, and the opening 10221 is distributed at an edge of the sub-pixel area. Based on this structure, the opening 10221 does not affect the sub-pixel area under a premise that the adhesion between the third planarization layer 1024 and the second electrode layer 1022 is sufficient.

Optionally, referring to FIG. 1, the counter substrate 102 further includes a black matrix (BM) 1026, and the black matrix 1026 is configured to shade the leakage light caused by poor liquid crystal orientation at the first through hole 10141 and the second through hole 10132a. The third planarization layer 1024 may flatten the black matrix 1026.

Optionally, the liquid crystal layer 103 includes ferroelectric liquid crystal. The ferroelectric liquid crystal refers to a liquid crystal material with ferroelectricity. A permanent electric dipole moment may be generated in the case that centers of positive and negative charges in the ferroelectric crystal cell do not coincide. Thus, the electric dipole moment may have spontaneous polarization below the Curie temperature, and under the action of an external electric field, the spontaneous polarization of the ferroelectric may change or even reverse the direction. In addition, the response time of ferroelectric liquid crystal may be up to 0.14 milliseconds, whereas ordinary liquid crystal may merely reach about 1.1 milliseconds. In response to a refresh frequency provided by the array substrate 101 being 3000 Hz, the ferroelectric liquid crystal enables the display panel according to the embodiment of the present disclosure to have a refresh rate of 750 Hz, which effectively improves the display effect of the display panel.

Optionally, referring to FIG. 1. the thin film transistor array 1012 includes a plurality of thin film transistors 10121 arranged in an array on the first base substrate 1011; and the array substrate 101 further includes a second planarization layer 1017 between the plurality of thin film transistors 10121 and the diffuse reflection layer 1013. The second planarization layer 1017 is configured to flatten a source line and a drain line in the thin film transistor 10121 to facilitate the manufacturing of subsequent structures.

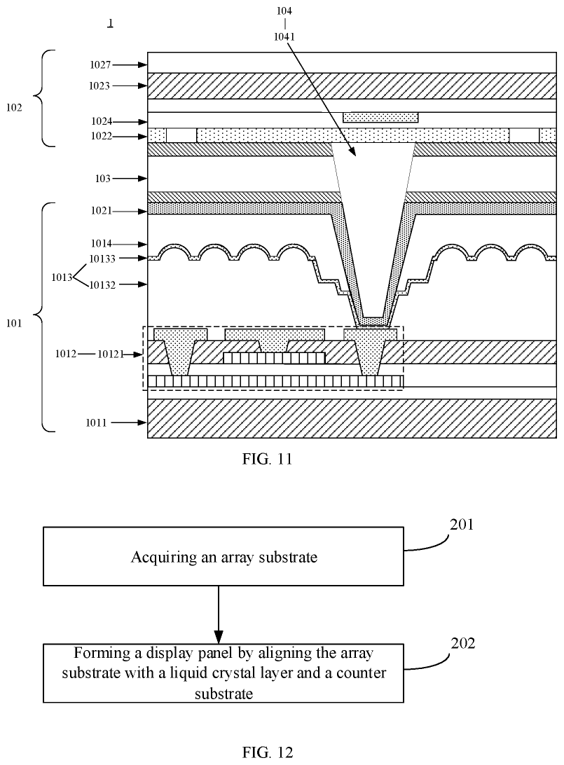

In an embodiment, the second planarization layer may be omitted, and the protrusion structure layer 10132 in the diffuse reflection layer 1013 is taken to achieve the function of the second planarization layer. FIG. 11 is a schematic structural diagram of another display panel according to an embodiment of the present disclosure. As shown in FIG. 11, the diffuse reflection layer 1013 is in direct contact with the thin film transistor array 1012, and the protrusion structure layer 10132 in the diffuse reflection layer 1013 implements the function of flattening the upper surface of the array substrate. Based on this structure, the display panel may have a reduced thickness, and thereby is applicable to a variety of scenes.

Optionally, the counter substrate 102 further includes a polarizer 1027 on a side, distal from the liquid crystal layer 103, of the second base substrate1023. The polarizer 1027 is configured to generate linearly polarized light, and a light transmission axis forms 45 degrees with an orientation direction of the liquid crystal. In the case that the liquid crystal layer 103 is not powered, the polarized light generated by the polarizer 1027 is reflected after passing through the liquid crystal, and keeps the polarization performance and operates in a bright state. In the case that the liquid crystal layer 103 is powered, the liquid crystal is equivalent to a quarter-wave plate, and the incident polarized light is changed to circularly polarized light after passing through the liquid crystal, and appears a reversed polarization performance and is in a dark state after being reflected by the liquid crystal. Meanwhile, a refractive index difference of the liquid crystal is 0.1. Under this refractive index difference, the thickness of the display panel 1 may be controlled between 1.38 nanometers and 1.6 nanometers. Therefore, the thickness of the display panel may be kept within this range by embedding the spacer in the deep hole.

Optionally, the counter substrate 102 further includes a color filter layer 1025 between the second base substrate 1023 and the third planarization layer 1024. In summary, the embodiment of the present disclosure provides a display panel that includes an array substrate, a counter layer, and a liquid crystal layer that are laminated. The first planarization layer between the diffuse reflection layer in the array substrate and the liquid crystal layer is capable of preventing impacts caused by the protrusion structure disposed on the diffuse reflection layer in the driving process of the liquid crystal layer. In addition, the protrusion structure is capable of diffusely reflecting the light irradiated to the surface thereof, such that a reflective display panel having a good display effect is achieved. Therefore, the problem in the related art regarding the poor display effect of the display panel is solved, and the display effect of the display panel is improved.

FIG. 12 shows a method for manufacturing a display panel according to an embodiment of the present disclosure. The method for manufacturing the display panel is applicable to manufacture the display panel shown in FIG. 1, and the method may include following processes.

In process 201, an array substrate is acquired.

In process 202, a display panel including the array substrate, a liquid crystal layer, and a counter substrate is formed.

The array substrate herein includes a first base substrate, and a thin film transistor array, a diffuse reflection layer, and a first planarization layer formed on the first base substrate. A surface, proximal to the first planarization layer, of the diffuse reflection layer is a reflection surface, wherein the reflection surface is provided with a plurality of protrusion structures configured to diffusely reflect light irradiated on the reflection surface.

In summary, the embodiment of the present disclosure provides a method for manufacturing a display panel. The display panel as manufactured by the method includes an array substrate, a counter layer, and a liquid crystal layer that are laminated. The first planarization layer between the diffuse reflection layer in the array substrate and the liquid crystal layer is capable of overcoming impacts caused by the protrusion structure disposed on the diffuse reflection layer in the driving process of the liquid crystal layer. In addition, the protrusion structure is capable of diffusely reflecting the light irradiated to the surface thereof, such that a reflective display panel having a good display effect is achieved. Therefore, the problem in the related art regarding the poor display effect of the display panel is solved, and the display effect of the display panel is improved.

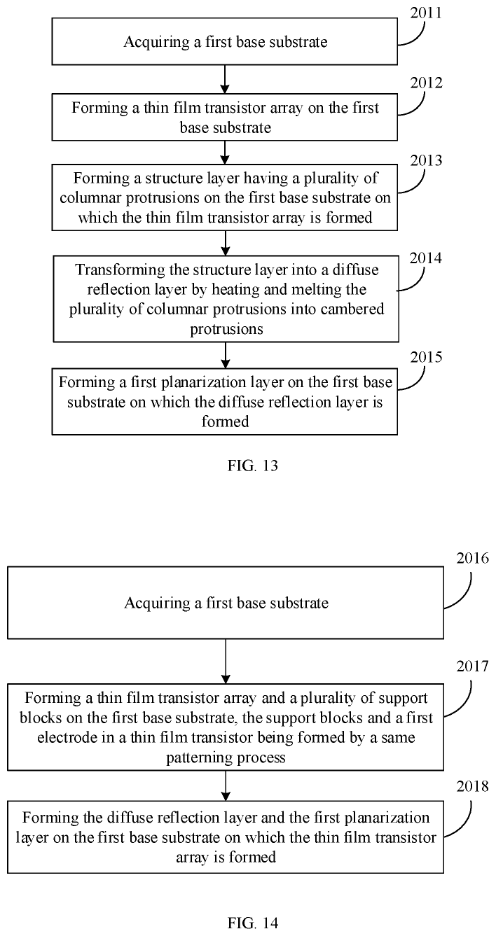

In an exemplary embodiment, as shown in FIG. 13, process 201 in the foregoing embodiment may include the following sub-processes.

In sub-process 2011, a first base substrate is acquired.

In sub-process 2012, a thin film transistor array is formed on the first base substrate.

The thin film transistor array includes a plurality of thin film transistors arranged in an array on the first base substrate.

In sub-process 2013, a structure layer having a plurality of columnar protrusions is formed on the first base substrate on which the thin film transistor array is formed.

The structure layer may be made of flexible organic polymer materials with a low melting point, such as resin. In addition, the material of the structure layer may also have reflection properties.

In sub-process 2014, the structure layer is transformed into the diffuse reflection layer by heating and melting the plurality of columnar protrusions into cambered protrusions.

The columnar protrusions, after being heating, are melted into cambered protrusions on the top. Then, the diffuse reflection layer is formed after cooling. It should be noted that the structure layer having a plurality of columnar protrusions may be made of a material with reflection properties. In the case that the material of the structure layer having the plurality of columnar protrusions does not have reflection properties, a reflection layer, such as a metal reflection layer, may be formed on the structure layer having cambered protrusions after the cambered protrusions are formed.

For parameters of the cambered protrusions, reference may be made to the foregoing embodiments, which are not repeated in the embodiment of the present disclosure.

In sub-process 2015, the first planarization layer is formed on the first base substrate on which the diffuse reflection layer is formed.

A fashion for forming the diffuse reflection layer is provided.

In an exemplary embodiment, as shown in FIG. 14, process 201 in the foregoing embodiment may include following sub-processes.

In sub-process 2016, a first base substrate is acquired.

In sub-process 2017, a thin film transistor array and a plurality of support blocks are formed on the first base substrate, wherein the support blocks and a first electrode in the thin film transistor are formed by a same patterning process.

In this way, it is not necessary to form the support block by a separate patterning process, which reduces one patterning process and simplifies the manufacturing process of the display panel.

Optionally, the thin film transistor array includes a plurality of thin film transistors arranged in an array on the first base substrate, wherein the thin film transistor includes a first electrode, a second electrode, and a third electrode configured to control connection or disconnection between the first electrode and the second electrode.

In sub-process 2018, a diffuse reflection layer and a first planarization layer are formed on the first base substrate on which the thin film transistor array is formed.

The diffuse reflection layer herein is provided with a plurality of protrusion structures on a surface proximal to the first planarization layer under supports of the plurality of support blocks.

This fashion provides another way to form the diffuse reflection layer.

FIGS. 13 and 14 show two fashions for forming the diffuse reflection layer. In the embodiment of the present disclosure, the diffuse reflection layer may be formed by selecting one of the fashions.

According to the embodiment of the present disclosure, a display device is further provided. The display device may include the display panel as defined in the foregoing embodiments, and may for example be a television, mobile phone, etc.

In the present disclosure, the terms such as “first,” “second,” and “third” are merely for illustration, and cannot be understood as indicating or implying relative importance. The term “a plurality of” means two or more in quantity, unless otherwise defined.

Described above are merely optional embodiments of the present disclosure, and are not intended to limit the present disclosure. Within the spirit and principles of the disclosure, any modifications, equivalent substitutions, improvements, and the like are within the protection scope of the present disclosure.

1. A display panel, comprising: an array substrate, a counter substrate, and a liquid crystal layer between the array substrate and the counter substrate; wherein
the array substrate comprises a first base substrate, and a thin film transistor array, a diffuse reflection layer, and a first planarization layer that are laminated on the first base substrate, wherein a surface, proximal to the first planarization layer, of the diffuse reflection layer is a reflection surface, the reflection surface being provided with a plurality of protrusion structures, the protrusion structures being configured to diffusely reflect light irradiated on the reflection surface.

2. The display panel according to claim 1, wherein the array substrate further comprises a plurality of support blocks between the diffuse reflection layer and the first base substrate, wherein the plurality of support blocks are disposed in orthographic projections of the plurality of protrusion structures on the first base substrate in one-to-one correspondence with the plurality of protrusion structures.

3. The display panel according to claim 2, wherein the thin film transistor array comprises a plurality of thin film transistors arranged in an array on the first base substrate, wherein the thin film transistor comprises a first electrode, a second electrode, and a third electrode configured to control connection or disconnection between the first electrode and the second electrode; and
the support block and the first electrode in the thin film transistor are disposed in a same layer.

4. The display panel according to claim 3, wherein the array substrate further comprises a support plate on which the plurality of support blocks are disposed.

5. The display panel according to claim 4, wherein the support plate and the third electrode in the thin film transistor are disposed in a same layer.

6. The display panel according to claim 1, wherein the protrusion structure is a cambered protrusion structure, and a ratio of a diameter of the protrusion structure to a height of the protrusion structure in a direction perpendicular to the first base substrate satisfies 3:1 to 15:1.

7. The display panel according to claim 6, wherein the protrusion structure is formed by melting and cooling a columnar protrusion.

8. The display panel according to claim 1, wherein
an orthographic projection of the protrusion structure on the first base substrate is square, and the orthographic projections of the plurality of protrusion structures on the first base substrate are arranged in rows and columns.

9. The display panel according to claim 1, wherein
the display panel further comprises a first electrode layer on a side, proximal to the first planarization layer, of the liquid crystal layer, and a second electrode layer on a side, distal from the first planarization layer, of the liquid crystal layer; and
the display panel further comprises a plurality of spacers comprising a first spacer, wherein an end of the first spacer abuts against the second electrode layer, and another end passes through the liquid crystal layer and abuts against the first electrode layer.

10. The display panel according to claim 9, wherein
the thin film transistor array comprises a plurality of thin film transistors arranged in an array on the first base substrate, wherein the thin film transistor comprises a first electrode, a second electrode, and a third electrode configured to control connection or disconnection between the first electrode and the second electrode; and
the first planarization layer is provided with a first through hole through which the first electrode layer is electrically connected to the first electrode, and an orthographic projection of the another end of the first spacer on the first planarization layer is disposed at the first through hole.

11. The display panel according to claim 10, wherein the diffuse reflection layer comprises a protrusion structure layer and a metal reflection layer covering the protrusion structure layer, wherein the protrusion structure layer is provided with a second through hole through which the metal reflection layer is electrically connected to the first electrode, and through which the first electrode layer is electrically connected to the metal reflection layer.

12. The display panel according to claim 9, wherein
the counter substrate comprises a second base substrate, and a third planarization layer and the second electrode layer laminated on a side, proximal to the liquid crystal layer, of the second base substrate; and
the counter substrate further comprises an adhesive structure, and the second electrode layer is provided with at least one opening in which the adhesive structure is disposed.

13. The display panel according to claim 1, wherein the liquid crystal layer comprises ferroelectric liquid crystal.

14. The display panel according to claim 1, wherein
the thin film transistor array comprises a plurality of thin film transistors arranged in an array on the first base substrate; and
the array substrate further comprises a second planarization layer between the plurality of thin film transistors and the diffuse reflection layer.

15. The display panel according to claim 1, wherein
the protrusion structure is a spherical protrusion structure, and a ratio of a diameter to a radius of the protrusion structure satisfies 1.3:1 to 1.6:1;
the display panel further comprises a plurality of support blocks between the diffuse reflection layer and the first base substrate, wherein the plurality of support blocks are disposed in orthographic projections of the plurality of protrusion structures on the first base substrate in one-to-one correspondence with the plurality of protrusion structures;
the thin film transistor array comprises a plurality of thin film transistors arranged in an array on the first base substrate, wherein the thin film transistor comprises a first electrode, a second electrode, and a third electrode configured to control connection or disconnection between the first electrode and the second electrode, and the support block and the first electrode in the thin film transistor are disposed in a same layer;
an orthographic projection of the protrusion structure on the first base substrate is square, and the orthographic projections of the plurality of protrusion structures on the first base substrate are arranged in rows and columns;
the display panel further comprises a first electrode layer on a side, proximal to the first planarization layer, of the liquid crystal layer, and a second electrode layer on a side, distal from the first planarization layer, of the liquid crystal layer;
the display panel further comprises a plurality of spacers comprising a first spacer, wherein an end of the first spacer abuts against the second electrode layer, and another end passes through the liquid crystal layer and abuts against the first electrode layer; and
the first planarization layer is provided with a first through hole through which the first electrode layer is electrically connected to the first electrode, and an orthographic projection of the another end of the first spacer on the first planarization layer is disposed at the first through hole.

16. A method for manufacturing a display panel, comprising:
acquiring an array substrate; and
forming a display panel comprising the array substrate, a liquid crystal layer, and a counter substrate; wherein
the array substrate comprises a first base substrate, and a thin film transistor array, a diffuse reflection layer, and a first planarization layer that are laminated on the first base substrate, wherein a surface, proximal to the first planarization layer, of the diffuse reflection layer is a reflection surface, the reflection surface being provided with a plurality of protrusion structures, the protrusion structures being configured to diffusely reflect light irradiated on the reflection surface.

17. The method according to claim 16, wherein acquiring the array substrate comprises:
acquiring a first base substrate;
forming the thin film transistor array on the first base substrate;
forming a structure layer having a plurality of columnar protrusions on the first base substrate on which the thin film transistor array is formed;
transforming the structure layer into the diffuse reflection layer by heating and melting the plurality of columnar protrusions into cambered protrusions; and
forming the first planarization layer on the first base substrate on which the diffuse reflection layer is formed.

18. The method according to claim 16, wherein acquiring the array substrate comprises:
acquiring a first base substrate;
forming the thin film transistor array and a plurality of support blocks on the first base substrate, wherein the thin film transistor array comprises a plurality of thin film transistors arranged in an array on the first base substrate, the thin film transistor comprising a first electrode, a second electrode, and a third electrode configured to control connection or disconnection between the first electrode and the second electrode, and the support block and the first electrode in the thin film transistor are formed by a same patterning process; and
forming the diffuse reflection layer and the first planarization layer on the first base substrate on which the thin film transistor array is formed, wherein the plurality of protrusion structures are formed on a surface, proximal to the first planarization layer, of the diffuse reflection layer under supports of the plurality of support blocks.

19. A display device, comprising a display panel, wherein the display panel comprises: an array substrate, a counter substrate, and a liquid crystal layer between the array substrate and the counter substrate; wherein
the array substrate comprises a first base substrate, and a thin film transistor array, a diffuse reflection layer, and a first planarization layer that are laminated on the first base substrate, wherein a surface, proximal to the first planarization layer, of the diffuse reflection layer is a reflection surface, the reflection surface being provided with a plurality of protrusion structures, the protrusion structures being configured to diffusely reflect light irradiated on the reflection surface.

20. The display panel according to claim 1, wherein
an orthographic projection of the protrusion structure on the first base substrate is circular or hexagonal, and the orthographic projections of the plurality of protrusion structures on the first base substrate are arranged in a form of honeycomb.
